(19) United States
(12) Patent Application Publication
(10) Pub. No.: US 2016/0247581 A1
(43) Pub. Date: Aug. 25, 2016

(54) MEMORY SYSTEM, MEMORY CONTROLLER AND MEMORY CONTROL METHOD

(71) Applicant: Kabushiki Kaisha Toshiba, Minato-ku (JP)

(72) Inventors: Riki SUZUKI, Yokohama (JP); Toshikatsu Hida, Yokohama (JP); Tokumasa Hara, Kawasaki (JP); Kenichiro Yoshii, Bunkyo (JP); Youhei Kouchi, Akishima (JP); Norikazu Yoshida, Kawasaki (JP)

(73) Assignee: Kabushiki Kaisha Toshiba, Minato-ku (JP)

(21) Appl. No.: 14/849,145

(22) Filed: Sep. 9, 2015

Related U.S. Application Data
(60) Provisional application No. 62/118,768, filed on Feb. 20, 2015.

(51) Int. Cl. G11C 29/00; G11C 16/10; G11C 16/26; G11C 16/08

(52) U.S. Cl. CPC G11C 29/76; G11C 16/08; G11C 16/10; G11C 16/26

(57) ABSTRACT

According to one embodiment, a memory system includes a nonvolatile memory, a memory interface, a storage unit which stores defective memory cell information, and a storage location control unit which creates second data of a second data length longer than a first data length based on an area at a write destination of first data of the first data length, causes the memory interface to write a plurality of second data to the nonvolatile memory, causes the memory interface to read the second data corresponding to the first data instructed to be read from the nonvolatile memory, and restores the first data based on the read second data and the defective memory cell information.

### CROSS-REFERENCE TO RELATED APPLICATIONS

This application is based upon and claims the benefit of priority from U.S. Provisional Application No. 62/118,768, filed on Feb. 20, 2015; the entire contents of which are incorporated herein by reference.

### FIELD

Embodiments described herein relate generally to a memory system, a memory controller, and a memory control method.

### BACKGROUND

In general, when data is written to a memory such as a NAND flash memory (hereinafter, referred to as a NAND memory), for an easy management of a storage location, data to be written at the same time is sequentially written in memory areas having the information indicating the memory areas (for example, adjacent memory cells) is consecutive in many cases. On the other hand, there often occurs that the writing is performed while avoiding a defective area (that is, a defective memory area in the memory). In a case where the writing is performed while avoiding the defective area, the data to be written at the same time may be not written in the memory areas having the information indicating the memory areas is not consecutive.

### BRIEF DESCRIPTION OF THE DRAWINGS

FIG. 1 is a block diagram illustrating an exemplary configuration of a storage device (a semiconductor storage device) according to an embodiment;

FIG. 2 is a diagram illustrating an exemplary configuration of a semiconductor memory unit of the embodiment;

FIG. 3 is a diagram illustrating an exemplary configuration of a block of a memory cell array of a two-dimensional structure;

FIG. 4 is a diagram illustrating an exemplary configuration of a block of a memory cell array of a three-dimensional structure;

FIG. 5 is a cross-sectional view of some parts of a memory cell array of a NAND memory of the three-dimensional structure;

FIG. 6 is a diagram illustrating an exemplary configuration of an encoder/decoder and a storage location control unit of the embodiment;

FIG. 7 is a diagram illustrating an exemplary configuration of the encoder/decoder and the storage location control unit of the embodiment in a case where randomization is performed;

FIG. 8 is a diagram illustrating a correspondence between one page of data and a physical address of the embodiment;

FIG. 9 is a diagram illustrating an example of a storage location of each codeword in a nonvolatile memory unit of the embodiment;

FIG. 10 is a diagram illustrating an example of an address conversion table of the embodiment;

FIG. 11 is a diagram illustrating an example of the storage location of each codeword in the nonvolatile memory unit of the embodiment in a case where a replacement process is performed;

FIG. 12 is a flowchart illustrating an example of a write procedure of the embodiment; and

FIG. 13 is a flowchart illustrating an example of a read procedure of the embodiment.

### DETAILED DESCRIPTION

According to the present embodiment, a memory system includes: a nonvolatile memory; a memory interface configured to control reading/writing of data with respect to the nonvolatile memory; and a defective memory cell information storage unit configured to store defective memory cell information of the nonvolatile memory. The memory system also includes a storage location control unit configured to, in response to a write instruction of a plurality of first data each having a first data length to the nonvolatile memory, create second data having a second data length longer than the first data length for each of the first data based on an area at a write destination of the first data and the defective memory cell information, and cause the memory interface to write a plurality of second data to the nonvolatile memory, and in response to a read instruction of the first data, cause the memory interface to read the second data corresponding to the first data instructed to be read from the nonvolatile memory, and restore the first data based on the read second data and the defective memory cell information.

A memory system, a memory controller, and a memory control method according to the embodiment will be described in detail hereinafter with reference to the appended drawings. Note that the present invention is not limited to the embodiment.

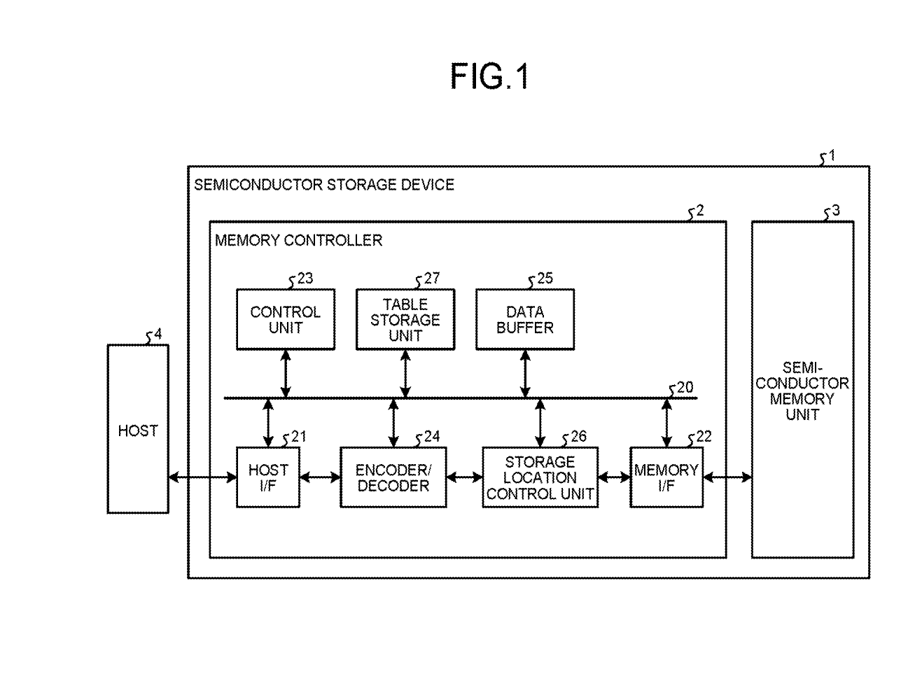

FIG. 1 is a block diagram illustrating an exemplary configuration of a storage device (the memory system) according to the embodiment. A semiconductor storage device 1 of this embodiment includes a memory controller 2 and a semiconductor memory unit (a nonvolatile memory) 3. The semiconductor storage device 1 is connectable to a host 4. In FIG. 1, a state in which the semiconductor storage device 1 is connected to the host 4 is shown. The host 4 is, for example, an electronic device such as a personal computer or a mobile terminal.

The semiconductor memory unit 3 is the nonvolatile memory (for example, a NAND memory) which stores data therein in a nonvolatile manner. Further, the description herein will be made about an example using the NAND memory as the semiconductor memory unit 3, but a storage device such as a three-dimensional flash memory, a Resistance Random Access Memory (ReRAM), a Ferroelectric Random Access Memory (FeRAM) other than the NAND memory may be used as the semiconductor memory unit 3. In addition, the description herein will be made about an example using the semiconductor memory as the storage device, but an error correction process of this embodiment may be applied to the storage device using the storage device other than the semiconductor memory.

The memory controller 2 controls the writing to the semiconductor memory unit 3 in response to a write command (request) from the host 4. In addition, the memory controller 2 controls the reading from the semiconductor memory unit 3 in response to a read command from the host 4. The memory controller 2 includes a host interface (host I/F) 21, a memory interface (memory I/F) 22, a control unit 23, an encoder/decoder 24, a data buffer 25, and a storage location control unit 26. The host I/F 21, the memory I/F 22, the control unit 23, the encoder/decoder 24, the data buffer 25, the storage location control unit 26, and a table storage unit 27 are connected to each other through an internal bus 20.

The host I/F 21 performs a process with respect to the host 4 according to an interface standard, and outputs a command and user data received from the host 4 through the internal bus 20. In addition, the host I/F 21 transmits the user data read out of the semiconductor memory unit 3 and a response from the control unit 23 to the host 4. Further, in this embodiment, data to be written to the semiconductor memory unit 3 in response to the write request from the host 4 will be referred to as the user data.

The memory I/F 22 performs a writing process of the data to the semiconductor memory unit 3 based on an instruction of the control unit 23. In addition, the memory I/F 22 performs a reading process on the semiconductor memory unit 3 based on the instruction of the control unit 23.

The control unit 23 is a control unit which collectively controls the respective components of the semiconductor storage device 1, and includes a Central Processing Unit (CPU), a Micro Controller Unit (MPU), and the like for example. In a case where a command is received from the host 4 through the host I/F 21, the control unit 23 performs control according to the command. For example, the control unit 23 instructs the memory I/F 22 to write the user data and a parity to the semiconductor memory unit 3 according to the command from the host 4. In addition, the control unit 23 instructs the memory I/F 22 to read the user data and the parity from the semiconductor memory unit 3 according to the command from the host 4. In addition, data other than the user data (that is, data used in internal control of the semiconductor storage device 1; hereinafter, referred to as control data) may be stored in the semiconductor memory unit 3. In this case, the control unit 23 also instructs the memory I/F 22 to write and read the control data.

The control unit 23 determines a storage area (a memory area) on the semiconductor memory unit 3 with respect to the user data accumulated in the data buffer 25. The user data is stored in the data buffer 25 through the internal bus 20. The control unit 23 determines the memory area for data (page data) of a page unit (a unit of writing). In the present specification, memory cells commonly connected to one word line are defined as a memory cell group. In a case where the memory cell is a multi-level cell, the memory cell group corresponds to a plurality of pages. For example, in a case where a 2-bit recordable (2 bit/cell) multi-level cell is used, the memory cell group corresponds to two pages. In a case where a 3-bit recordable (3 bit/cell) multi-level cell is used, the memory cell group corresponds to three pages. In the present specification, the user data to be written in one page is defined as a unit data. In addition, the semiconductor memory unit 3 is erased in a unit called a block. One block includes a plurality of memory cell groups.

The control unit 23 determines the memory area of the semiconductor memory unit 3 at a writing destination for each unit data. A physical address is assigned to the memory area of the semiconductor memory unit 3. The control unit 23 manages the memory area at the writing destination of the unit data using the physical address. The control unit 23 designates the determined memory area (the physical address) and instructs the memory I/F 22 to write the user data to the semiconductor memory unit 3. A correspondence between a logical address of the user data received from the host and the physical address indicating the storage area on the semiconductor memory unit 3 storing the user data is stored the table storage unit 27 as an address conversion table. The logical address is an address of the user data managed by the host 4. In other words, the logical address is information used for identifying the user data managed by the host 4. The address conversion table may directly indicate the correspondence between the logical address and the physical address, or may be a multi-stage table. The multi-stage table is a plurality of tables which is used for once converting the logical address into an intermediate address and then converting the intermediate address into the physical address.

In addition, in a case where a read request is received from the host 4, the control unit 23 converts the logical address designated in response to the read request into the physical address using the above-mentioned address conversion table, and instructs the memory I/F 22 to perform the reading from the physical address. Further, as described above, in this embodiment, since the data obtained by dividing the unit data into plural data is encoded to generate codewords, a plurality of codewords are included in the data of a unit of writing (that is, the data of one page). In this embodiment, the physical address in the address conversion table is managed in a codeword unit in order to enable the reading from the semiconductor memory unit 3 in the codeword unit. Further, when the reading from the semiconductor memory unit 3 in the codeword unit is performed, the data of one page containing the codeword instructed for the reading is once read out of the semiconductor memory unit 3. Then, the semiconductor memory unit 3 outputs the codeword instructed for the reading in the data of one page to the memory controller 2.

The data buffer 25 temporarily stores the user data received from the host 4 by the memory controller 2 until the data is stored in the semiconductor memory unit 3. In addition, the data buffer 25 temporarily stores the user data read out of the semiconductor memory unit 3 until the data is transmitted to the host 4. The data buffer 25, for example, is configured by a general-purpose memory such as a Static Random Access Memory (SRAM) or a Dynamic Random Access Memory (DRAM).

The user data transmitted from the host 4 is transferred to the internal bus 20 and stored in the data buffer 25. The encoder/decoder 24 encodes the data (the user data and the control data) stored in the semiconductor memory unit 3 to generate the codeword. A method of encoding the user data and a method of encoding the control data may be equal to or different from each other. In addition, any method may be employed as the encoding method. For example, a Reed Solomon (RS) encoding, a Bose Chaudhuri Hocquenghem (BCH) encoding, and a Low Density Parity Check (LDPC) encoding may be used. In addition, the encoder/decoder 24 performs a decoding process of the codeword read out of the semiconductor memory unit 3.

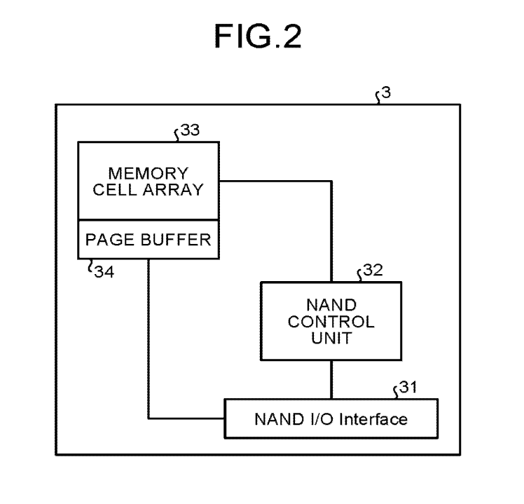

As described above, the semiconductor memory unit 3 in this embodiment is the NAND memory. FIG. 2 is a diagram illustrating an exemplary configuration of the semiconductor memory unit 3 of this embodiment. As illustrated in FIG. 2, the semiconductor memory unit 3 includes a NAND I/O interface 31, a NAND control unit 32, a memory cell array (a NAND memory cell array) 33, and a page buffer 34.

The NAND I/O Interface 31 controls inputting/outputting with an external device such as the memory controller 2. In a case where a command such as a write request or a read request is input from the outside, the NAND I/O Interface 31 inputs the command to the NAND control unit 32. The NAND control unit 32 controls the operation of the semiconductor memory unit 3 based on the command input from the NAND I/O Interface 31. Specifically, in a case where the write request is input, the data requested for the writing is controlled to be written into an area designated on the memory cell array 33. In addition, in a case where the read request is input, the NAND control unit 32 controls the data requested for the reading to be read out of the memory cell array 33. The data read out of the memory cell array 33 is stored in the page buffer 34. In this embodiment, at the time of the reading, the reading can be made in the codeword unit smaller than the page unit as described above, and in a case where the reading is requested in the codeword unit, the data requested for the reading is output from the memory controller 2 in the data stored in the page buffer 34.

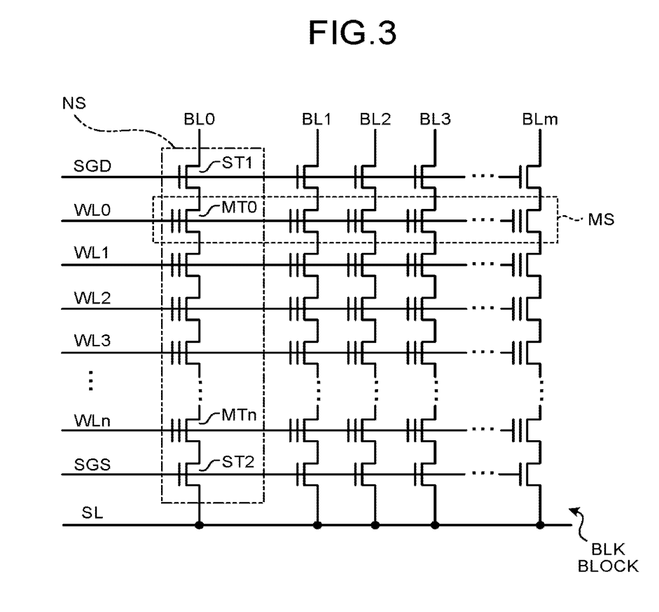

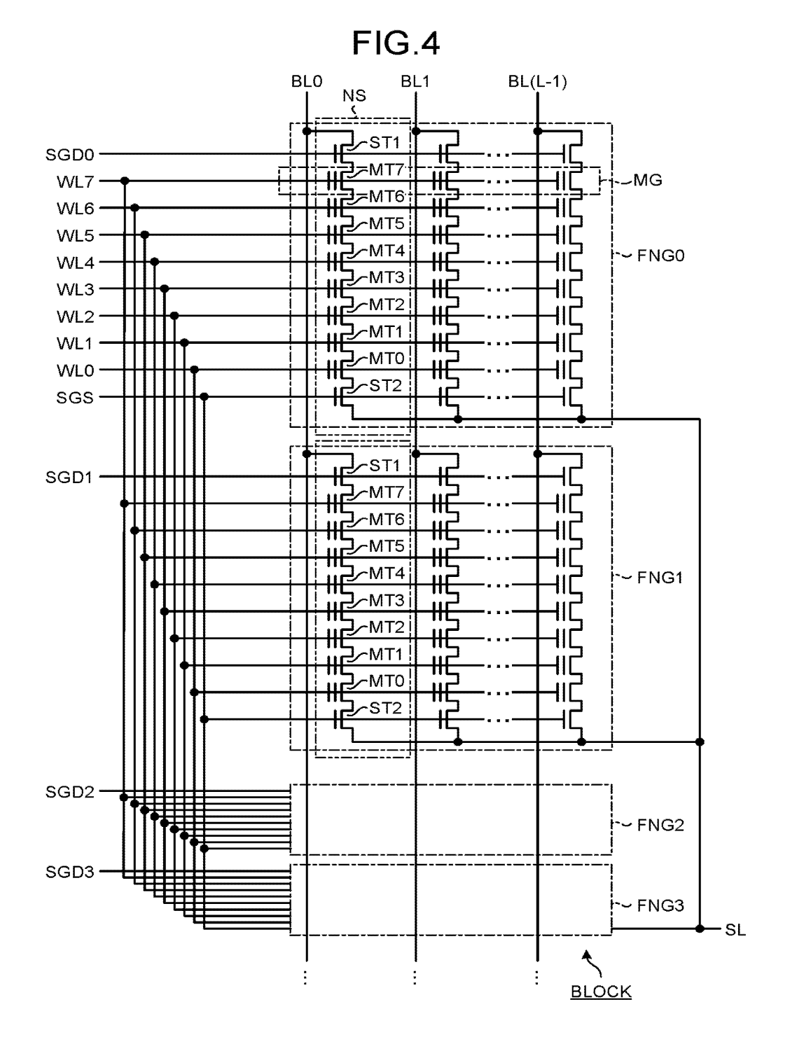

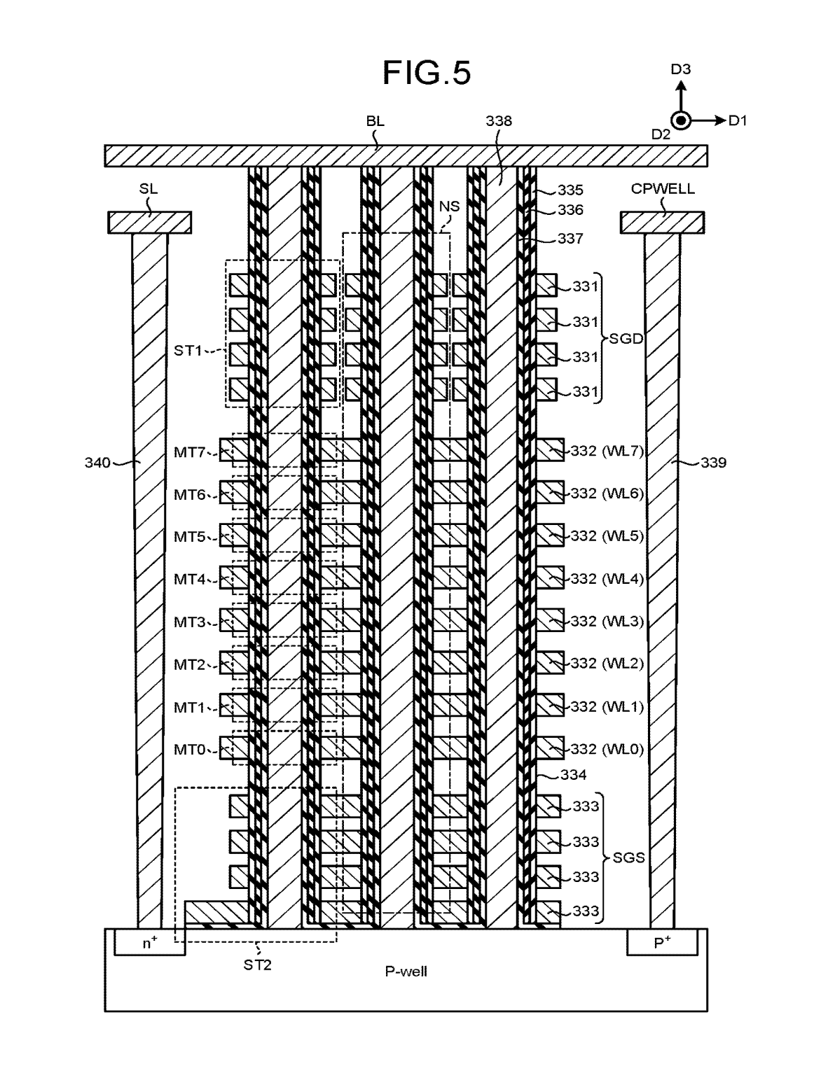

There is no particular restriction on the configuration of the memory cell array 33 assumed in this embodiment. The memory cell array may have a two-dimensional structure as illustrated in FIG. 3, or may have a three-dimensional structure as illustrated in FIGS. 4 and 5. Furthermore, the memory cell array may have other structures.

FIG. 3 is a diagram illustrating an exemplary configuration of a block of the memory cell array of the two-dimensional structure. FIG. 3 illustrates one block among the blocks included in the memory cell array of the two-dimensional structure. Other blocks of the memory cell array also have the same configuration as that of FIG. 3. As illustrated in FIG. 3, a block BLK of the memory cell array includes (m+1) NAND strings NS (m is an integer of 0 or more). Each NAND string NS includes (n+1) memory cell transistors MT0 to MTn (n is an integer of 0 or more) which are connected in series and share a diffusion area (a source area or a drain area) between adjacent memory cell transistors MT, and select transistors ST1 and ST2 which are disposed at both ends of a column of the (n+1) memory cell transistors MT0 to MTn.

Word lines WL0 to WLn are connected to control gate electrodes of the memory cell transistors MT0 to MTn constituting the NAND string NS, and the memory cell transistors MTi (i=0 to n) in the respective NAND string NS are commonly connected by the same word line WLi (i=0 to n). In other words, the control gate electrodes of the memory cell transistors MTi in the same row in the block BLK are connected to the same word line WLi.

Each of the memory cell transistors MT0 to MTn is configured by a field effect transistor having a stacked gate structure formed on a semiconductor substrate. Herein, in the stacked gate structure, a charge accumulation layer (a floating gate electrode) which is formed through a gate insulation film on the semiconductor substrate and the control gate electrode which is formed on the charge accumulation layer with the gate insulation film interposed therebetween are included. The memory cell transistors MT0 to MTn have threshold voltages which are changed according to the number of electrons accumulated in the floating gate electrode, and the data can be stored according to a difference of the threshold voltage.

Bit lines BL0 to BLm each are connected to the drains of the (m+1) select transistors ST1 in one block BLK, and a select gate line SGD is commonly connected to the gates. In addition, the source of the select transistor ST1 is connected to the drain of the memory cell transistor MT0. Similarly, a source line SL is commonly connected to the sources of the (m+1) select transistors ST2 in one block BLK, and a select gate line SGS is commonly connected to the gates. In addition, the drain of the select transistor ST2 is connected to the source of the memory cell transistor MTn.

Each memory cell is connected to the word lines and also to the bit lines. Each memory cell can be identified by an address for identifying the word lines and an address for identifying the bit lines. As described above, the data of the memory cell (the memory cell transistor MT) in the same block BLK is collectively erased. On the other hand, the reading and writing of the data are performed in a unit of a plurality of memory cells commonly connected to any one of the word lines WL (that is, a memory group unit).

FIG. 4 is a diagram illustrating an exemplary configuration of the block of the memory cell array of the three-dimensional structure. FIG. 4 illustrates one block BLK among the plurality of blocks constituting the memory cell array of the three-dimensional structure. Other blocks of the memory cell array also have the same configuration as that of FIG. 4.

As illustrated in the drawing, the block BLK, for example, includes four fingers FNG (FNG0 to FNG3). In addition, each finger FNG includes a plurality of NAND strings NS. Each of the NAND strings NS, for example, includes eight memory cell transistors MT (MT0 to MT7) and the select transistors ST1 and ST2. Further, the number of memory cell transistors MT is not limited to “8”. The memory cell transistors MT are disposed such that current paths thereof are connected in series between the select transistors ST1 and ST2. The current path of the memory cell transistor MT7 on one end side of the serial connection is connected to one end of the current path of the select transistor ST1, and the current path of the memory cell transistor MT0 on the other side is connected to one end of the current path of the select transistor ST2.

The gates of the respective select transistors ST1 of the fingers FNG0 to FNG3 each are commonly connected to select gate lines SGD0 to SGD3. On the other hand, the gates of the select transistors ST2 are commonly connected to the same select gate line SGS among a plurality of fingers FNG. In addition, the control gates of the memory cell transistors MT0 to MT7 in the same block BLK0 each are commonly connected to the word lines WL0 to WL7. In other words, the word lines WL0 to WL7 and the select gate line SGS are commonly connected among the plurality of fingers FNG0 to FNG3 in the same block BLK, but the select gate lines SGD are independently connected to the fingers FNG0 to FNG3 even in the block BLK.

The word lines WL0 to WL7 each are connected to the control gate electrodes of the memory cell transistors MT0 to MT7 constituting the NAND string NS, and the memory cell transistors MTi (i=0 to n) in the respective NAND strings NS are commonly connected by the same word lines WLi (i=0 to n). In other words, the control gate electrodes of the memory cell transistors MTi in the same row in the block BLK are connected to the same word lines WLi.

Each memory cell is connected to the word lines and also to the bit lines. Each memory cell can be identified by an address for identifying the word lines and an address for identifying the bit lines. As described above, the data of the memory cell (the memory cell transistor MT) in the same block BLK is collectively erased. On the other hand, the reading and writing of the data are performed in a unit of a plurality of memory cell groups MG which are commonly connected to any one of the word lines WL.

FIG. 5 is a cross-sectional view of some parts of a memory cell array of the NAND memory of the three-dimensional structure. As illustrated in FIG. 5, the plurality of NAND strings NS are formed on a p-type well area (P-well). In other words, a plurality of wiring layers 333 serving as the select gate lines SGS, a plurality of wiring layers 332 serving as the word lines WL, and a plurality of wiring layers 331 serving as the select gate lines SGD are formed on the p-type well area.

Then, a memory hole 334 leading to the p-type well area is formed through these wiring layers 333, 332, and 331. In the side surface of the memory hole 334, a block insulation film 335, a charge accumulation layer 336, and a gate insulation film 337 are sequentially formed, and a conductive film 338 is buried in the memory hole 334. The conductive film 338 serves as the current path of the NAND string NS, and is an area where a channel is formed at the time of the operation of the memory cell transistor MT and the select transistors ST1 and ST2.

In each NAND string NS, the select transistor ST2, the plurality of memory cell transistors MT, and the select transistor ST1 are sequentially stacked on the p-type well area. The wiring layer serving as the bit line BL is formed on the upper end of the conductive film 338.

Furthermore, an n+ type impurity diffusion layer and a p+ type impurity diffusion layer are formed in the surface of the p-type well area. A contact plug 340 is formed on the n+ type impurity diffusion layer, and the wiring layer serving as the source line SL is formed on the contact plug 340. In addition, a contact plug 339 is formed on the p+ type impurity diffusion layer, and the wiring layer serving as a well wiring CPWELL is formed on the contact plug 339.

A plurality of the above configurations illustrated in FIG. 5 are arranged in a depth direction of the sheet surface of FIG. 5, and a set of the plurality of NAND strings are aligned in a line in the depth direction, so that one finger FNG is formed.

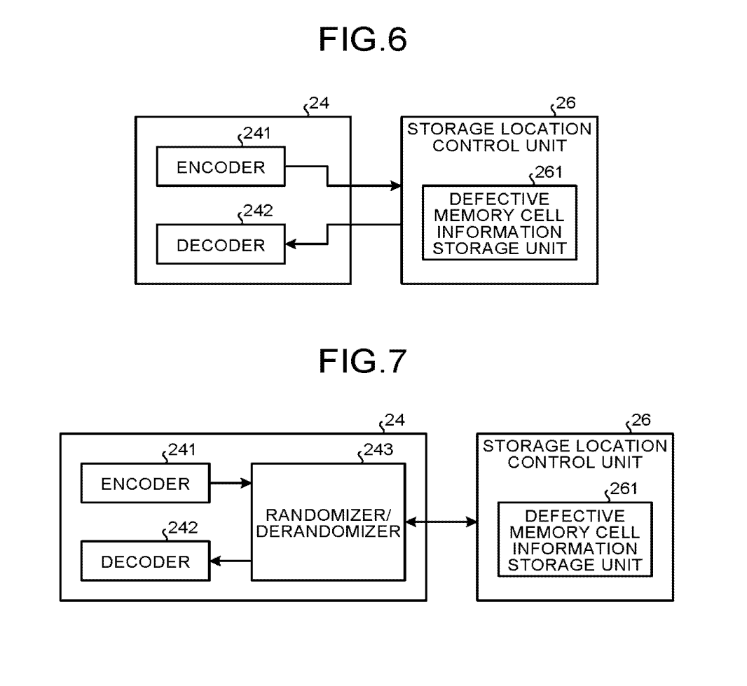

Next, the write process and the read process of this embodiment will be described. FIG. 6 is a diagram illustrating an exemplary configuration of the encoder/decoder 24 and the storage location control unit 26 of this embodiment. The encoder/decoder 24 includes an encoder 241 and a decoder 242. The storage location control unit 26 includes a defective memory cell information storage unit 261. Further, FIG. 6 illustrates an example where the storage location control unit 26 is independently provided, but the storage location control unit 26 may be provided in the memory I/F 22, or may be provided in the control unit 23.

The encoder 241 encodes division data which is data obtained by dividing the unit data into plural data to generate a codeword. The codeword generated by the encoder 241 is input to the storage location control unit 26. The storage location control unit 26 stores defective memory cell information (defective information) which is information indicating a location of a defective memory cell (a defective memory area) of the semiconductor memory unit 3 in the defective memory cell information storage unit 261. The defective memory cell information, for example, may be bitmap information indicating whether each semiconductor memory cell is the defective memory cell or information specifying a location of the defective memory cell, and any type of information may be employed. In addition, the defective memory cell information is obtained at the test before shipping the semiconductor memory unit 3, and stored in the defective memory cell information storage unit 261. For example, the defective memory cell information is obtained from the semiconductor memory unit 3 by inputting a command for the confirmation on whether there is a defective memory cell in the semiconductor memory unit 3 at the test before shipping. In addition, the command may set to be input from the memory controller 2 to the semiconductor memory unit 3 after shipping so as to update the defective memory cell information.

The storage location control unit 26 performs a process of writing the codeword output from the encoder 241 to the semiconductor memory unit 3 while avoiding the defective memory cell based on the defective memory cell information. Specifically, for example, as to be described below, a skip process of writing the codeword while skipping the defective memory cell, or a replacement process of writing the codeword to a redundant area which is determined in advance instead of writing the codeword to the defective memory cell is performed on the codeword output from the encoder 241, and the processing result (defect avoidance data) is output to the memory I/F 22. Hereinafter, a process of writing the codeword to the semiconductor memory unit 3 while avoiding the defective memory cell will be called a defective cell avoidance process. The memory I/F 22 outputs the defect avoidance data output from the storage location control unit 26 to the semiconductor memory unit 3 together with the physical address (a storage location on the semiconductor memory unit 3) instructed from the control unit 23. Further, as described above, since the encoder 241 encodes the data obtained by dividing the unit data into plural data, a plurality of codewords are included in the write unit (that is, the data of one page). Therefore, in this embodiment, the semiconductor memory unit 3 writes the processing result output from the storage location control unit 26 into a storage location corresponding to the instructed physical address.

At the time of reading the codeword from the semiconductor memory unit 3, the memory I/F 22 designates the physical address at which the reading is instructed from the control unit 23, and instructs the reading from the semiconductor memory unit 3. The data read out of the semiconductor memory unit 3 is input to the storage location control unit 26 through the memory I/F 22. The storage location control unit 26 determines whether the read-out data is subjected to the defective cell avoidance process at the time of the reading based on the defective memory cell information. In a case where it is determined that the data is subjected to the defective cell avoidance process, a reverse process of the defective cell avoidance process is performed to restore the data equivalent to the codeword, and inputs the restored data to the decoder 242. Further, the data equivalent to the codeword is data which may have an error in the written codeword. In a case where the input data is restored and no error is found, the decoder 242 writes the data equivalent to the user data in the input data to the data buffer 25. In addition, in a case where there is an error in the input data, the decoder 242 corrects the error and writes the data equivalent to the user data after the error correction to the data buffer 25.

In addition, in a case where the data written to the semiconductor memory unit 3 is randomized, the encoder/decoder 24 may be configured as illustrated in FIG. 7. FIG. 7 is a diagram illustrating an exemplary configuration of the encoder/decoder 24 and the storage location control unit 26 of this embodiment in a case where the randomization is performed. In the example of FIG. 7, the encoder/decoder 24 includes the encoder 241, the decoder 242, and a randomizer/derandomizer 243. The operation and the configuration of the storage location control unit 26 are identical with or similar to the example of FIG. 6.

The operations of the encoder 241 and the decoder 242 in an exemplary configuration of FIG. 7 are identical with or similar to those of the exemplary configuration of FIG. 6. At the time of the writing to the semiconductor memory unit 3, the codeword output from the encoder 241 is randomized by the randomizer/derandomizer 243 and input to the storage location control unit 26. In addition, at the time of the reading from the semiconductor memory unit 3, the data input from the storage location control unit 26 is derandomized by the randomizer/derandomizer 243, and then input to the decoder 242.

Next, the defective cell avoidance process of this embodiment will be described. As the defective cell avoidance process, as described above, there is the skip process of writing the codeword while skipping the defective memory cell and the replacement process of writing the codeword to the redundant area which is determined in advance instead of writing the codeword to the defective memory cell. Even in the case of using any one of the above methods, the redundant area is secured for a defective cell process in the memory area corresponding to the data of one page in order to complete these processes in one page unit, and the processes are performed using the redundant area. For example, the redundant area is simply provided at the last (the end) of the memory area of one page. In other words, when the data length of one codeword is set to α bits, the unit data is divided into n division data and encoded, and the memory area of one page is set to m bits, m−n×α bits at the last of the memory area of one page is assumed to be the redundant area. In this case, when the codeword is written to the semiconductor memory unit 3 using the skip process (that is, a process of sequentially writing the data to be written to the defective memory cell to the next memory cell of the defective memory cell so as to shift the memory cell backward), the end location (a storage location in the word line of the semiconductor memory unit 3) of the codeword is sequentially shifted by the number of skipped bits, and the last codeword is stored outside the redundant area. Therefore, in a case where the reading is performed in the codeword unit, there is a need to perform a process of calculating the physical address corresponding to the head of each codeword, so that time is taken for the reading. In addition, in a case where the codeword is written to the semiconductor memory unit 3 through the replacement process, the corresponding data is stored in the redundant area instead of the defective memory cell. Therefore, in a case where the reading is performed in the codeword unit, there is a need to calculate a storage location for each defective memory cell, so that time is taken for the reading.

In this regard, in this embodiment, the redundant area is not collectively provided at the last of the memory area of one page, but the redundant area for the defective cell avoidance process is provided for each codeword, so that an decreasing of the reading speed is prevented. Therefore, in this embodiment, at the time of the reading from the semiconductor memory unit 3, there is no need to calculate the head address of the reading, so that a variation in time taken until the read data is output disappears. In addition, in a case where the redundant area is collectively provided at the last of the memory area of one page, there is a need to temporarily store the defective memory cell information of the entire page containing the read data at the time of the reading, but in this embodiment, the defective memory cell information may be temporarily stored in each area obtained by dividing one page instead of the entire one page. Therefore, it is possible to reduce the memory area for temporarily storing the defective memory cell information compared to the case where the redundant area is collectively provided at the last of the memory area of one page.

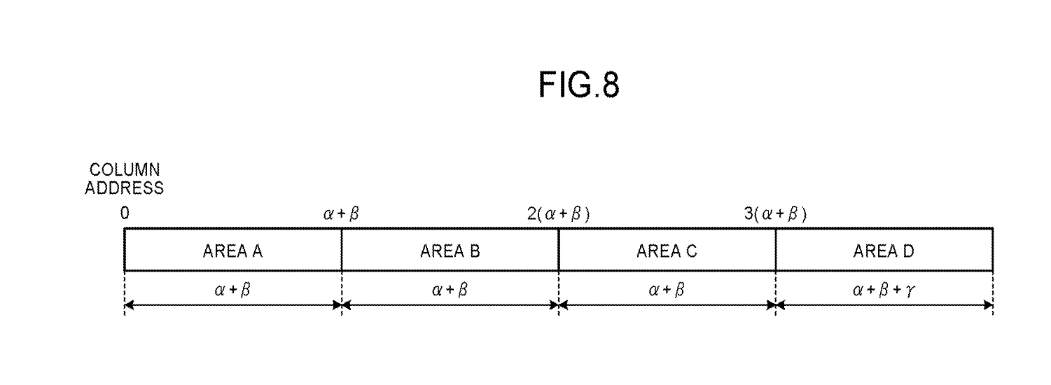

FIG. 8 is a diagram illustrating a correspondence between the data of one page of this embodiment and the physical address. In this embodiment, the data of one page is divided into four areas Area A, Area B, Area C, and Area D as illustrated in FIG. 8. Further, FIG. 8 illustrates an example in which four codewords are included in the data of one page. A column address of FIG. 8 is an address indicating the bit line connected to the memory cell in the semiconductor memory unit 3. In this embodiment, the storage location of each codeword is managed by a page address and the column address which are addresses in the semiconductor memory unit 3 of the page unit. In other words, a set of the page address and the column address is managed as the physical address using the address conversion table.

As illustrated in FIG. 8, in this embodiment, the data of one page is associated with the column address illustrated in FIG. 8. In other words, as illustrated in FIG. 8, when α is set as a bit length of each codeword output from the encoder 241, α+β bits corresponding to the column addresses from 0 to α+β−1 are set as Area A, α+β bits corresponding to the column addresses from α+β to 2(α+β)−1 are set as Area B, α+β bits corresponding to the column addresses from 2(α+β) to 3(α+β)−1 are set as Area C, and α+β+γ bits corresponding to the column addresses from 3(α+β) to the last are set as Area D. Area A, Area B, Area C, and Area D each correspond to one codeword. Further, β is a redundant area for the defective cell avoidance process, and γ is a value satisfying γ=m−4(α+β) when the data of one page is m bits. β is “1” or more, and γ may be “0”.

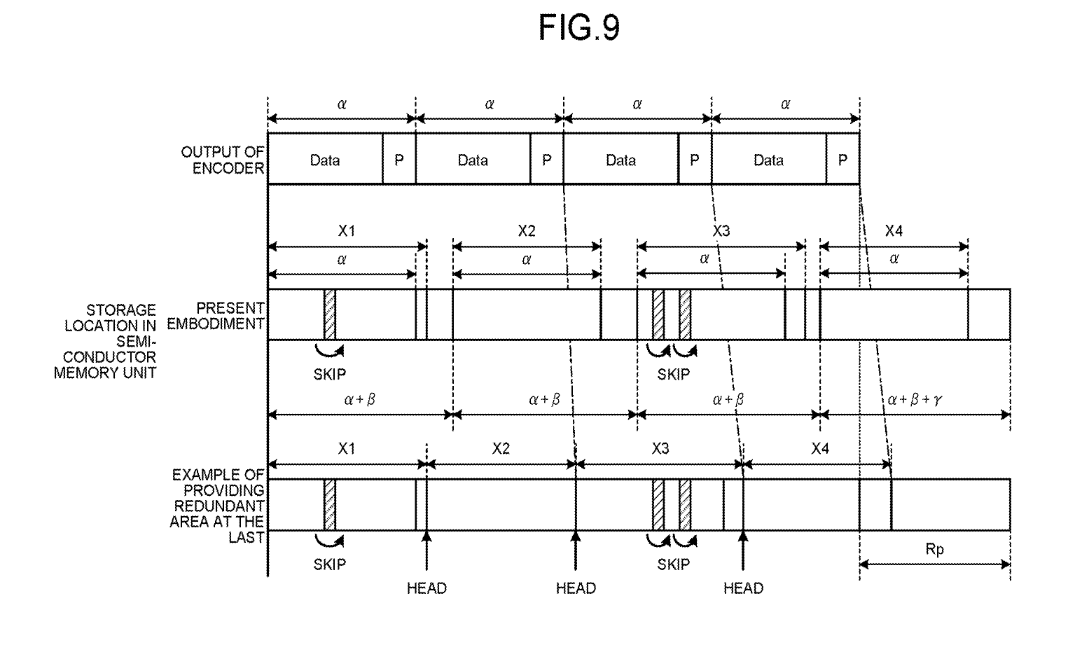

FIG. 9 is a diagram illustrating an example of the storage location in a nonvolatile memory unit 3 of each codeword of this embodiment. In a first stage of FIG. 9, four codewords of one page output from the encoder 241, (that is, generated by the encoder 241), is illustrated. In FIG. 9, “Data” indicates the divided unit data, and “P” (Parity) indicates a redundant bit generated by the encoding. Further, FIG. 9 illustrates an example in which each codeword is composed of “Data” and “Parity”, but the codeword generated by the encoder 241 may be a codeword which is not divided into “Data” and “Parity”. FIG. 9 illustrates an example in which the skip process is performed as the defective cell avoidance process. In a second stage of FIG. 9, the storage location of each codeword in the nonvolatile memory unit 3 is illustrated in a case where the defective cell avoidance process of this embodiment is performed using the correspondence of the physical address illustrated in FIG. 8. In a third stage of FIG. 9, for the sake of comparison, the storage location of each codeword in the nonvolatile memory unit 3 is illustrated in a case where the redundant area (Rp bits) for the defective cell avoidance process is collectively provided at the last of the memory area of one page and the defective cell avoidance process (the skip process) is performed.

In FIG. 9, a hatched area illustrates the defective memory cell. As illustrated in the second stage of FIG. 9, the storage location of the end of a first codeword which is a codeword to be written in the first area on the left side (corresponding to Area A of FIG. 8) is shifted to the right side by an amount of the defective memory cell by skipping the defective memory cell. Therefore, the bit length from the head to the end of the first codeword becomes X1 bits (X1 memory cells). Similarly, the storage location of the end of a third codeword which is a codeword to be written in the third area on the left side (corresponding to Area C of FIG. 8) is shifted to the right side by an amount of the defective memory cell. Therefore, the bit length from the head to the end of the third codeword becomes X3 bits (X3 memory cells). There is no defective memory cell in the second and fourth areas on the left side (corresponding to Areas B and D of FIG. 8). Therefore, when the bit lengths from the heads to the ends of a second codeword and a fourth codeword each become X2 bits and X4 bits, X2 and X4 becomes “α” (that is, X2=X4=α).

As illustrated in the second stage of FIG. 9, in this embodiment, the head locations of the respective storing codewords are matched with the heads of the areas for storing the respective codewords predefined in FIG. 8. Therefore, there is no need to calculate the head location for each codeword in the page. In this regard, in the example illustrated at the third stage of FIG. 9, the head of each codeword is shifted at every skipping due to the defective memory cell, so that the head location of the codeword becomes different in each page. Therefore, in the example illustrated at the third stage of FIG. 9, as described above, in a case where the reading is performed in the codeword unit, there is a need to perform a process of calculating the physical address corresponding to the head of each codeword, so that time is taken for the reading.

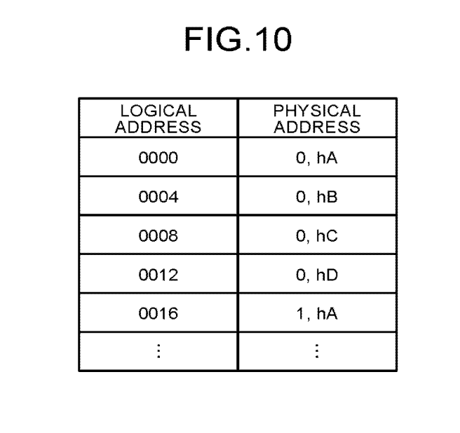

In this embodiment, there is no need to calculate the physical address (the column address) of the head of each codeword in each page, and it is possible to perform the reading for each codeword using a fixed column address as long as the location of the codeword in the page can be confirmed. FIG. 10 is a diagram illustrating an example of the address conversion table of this embodiment. As illustrated in FIG. 10, the physical address includes information containing two addresses (the page address and the column address). For example, the data at the logical address “0000” is associated with the physical address “0, hA” of FIG. 10. “hA”, “hB”, “hC”, and “hD” are identification information indicating the column addresses of the heads of the respective codewords of Areas A, B, C, and D illustrated in FIG. 8. The identification information indicating the column address, for example, is information indicating the location of the codeword in the page. In this embodiment, since the head location of each codeword in the page is fixed, the column address can be easily obtained from the information indicating the location of the codeword in the page. Further, “X, Y” at the physical address means that the page address is “X” and the identification information indicating the column address is “Y”.

Further, in a case where the skip process illustrated in FIG. 9 is performed, the storage location control unit 26 sequentially outputs the input codewords to the memory I/F 22. At this time, as data at a bit location where the writing destination corresponds to the defective memory cell among the codewords, the storage location control unit 26 outputs an arbitrary value (for example, “1”) instead of the data at the subject bit location of the codeword and outputs the data at the subject bit location of the codeword after the arbitrary value is output based on the defective memory cell information. In other words, the storage location control unit 26 outputs the data with the arbitrary value inserted to the bit location where the writing destination corresponds to the defective memory cell with respect to the codeword output from the encoder 241. In other words, the arbitrary value (fourth data) having the same length as the subject data is inserted before the data (third data) at the bit location where the writing destination corresponds to the defective memory cell. Thereafter, the storage location control unit 26 outputs the arbitrary value (for example, “1”) until the bit length from the head of the codeword becomes α+β bits. In this way, the data output from the storage location control unit 26 is the defect avoidance data in the above-mentioned storage location control unit 26.

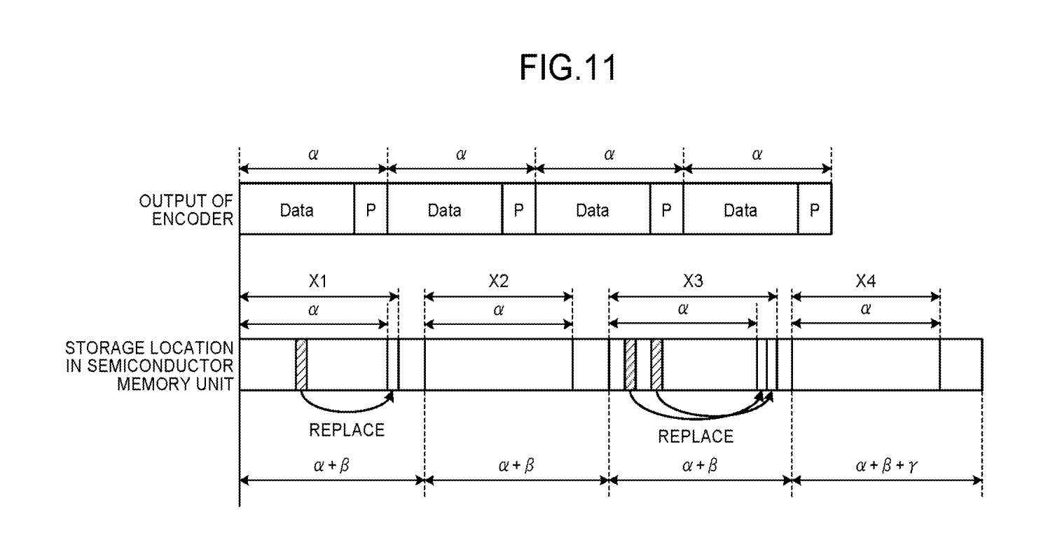

In addition, the description in FIG. 9 has been made about an example where the skip process is performed as the defective cell avoidance process, but the replacement process may be performed as the defective cell avoidance process. FIG. 11 is a diagram illustrating an example of the storage location in the nonvolatile memory unit 3 of each codeword of this embodiment in a case where the replacement process is performed. A first stage of FIG. 11 is the same as the first stage of the example of FIG. 9. A second stage of FIG. 11 illustrates the storage location of each codeword in the nonvolatile memory unit 3 in a case where the replacement process is performed using the correspondence of the physical address illustrated in FIG. 8. In a case where the replacement process is performed, α bits in the head are generally defined as a write area in each area illustrated in FIG. 8, β bits in the last (the end) are defined as the redundant area for the replacement process. Then, the replacement process in this embodiment is performed in each of Areas A, B, C, and D illustrated in FIG. 8. In other words, for example, in a case where there is a defective memory cell in the first area on the left (corresponding to Area A of FIG. 8), the data is written in the β bits in the end of the area instead of writing the data in the subject defective memory cell. In this way, through the replacement process performed on each area, similarly to the example of FIG. 9, there is no need to calculate the physical address (the column address) of the heat of each codeword in each page, and it is possible to perform the reading for each codeword using a fixed column address as long as the location of the codeword in the page can be confirmed.

Further, in a case where the replacement process illustrated in FIG. 11 is performed, the storage location control unit 26 sequentially outputs the input codewords to the memory I/F 22. At this time, instead of the data (fifth data) at the subject bit location (a first bit location) of the codeword as data at a bit location where the writing destination corresponds to the defective memory cell among the codewords, the storage location control unit 26 outputs an arbitrary value (for example, “1”), outputs the data at the bit location (a second bit location) next to the first bit location of the codeword after the arbitrary value is output based on the defective memory cell information, and outputs the data (sixth data) at the first bit location of the codeword after the data in the end of the codeword is output. Then, the storage location control unit 26 outputs the arbitrary value (for example, “1”) until the bit length from the head of the codeword becomes α+β bits. In this way, the data output from the storage location control unit 26 is the defect avoidance data in the above-mentioned storage location control unit 26.

Further, the above description has been made on an assumption of an exemplary configuration of FIG. 6, and in the exemplary configuration of FIG. 7 (that is, in a case where the randomization is performed), the storage location control unit 26 performs the skip process the replacement process as described above on the codeword after being subjected to the randomization.

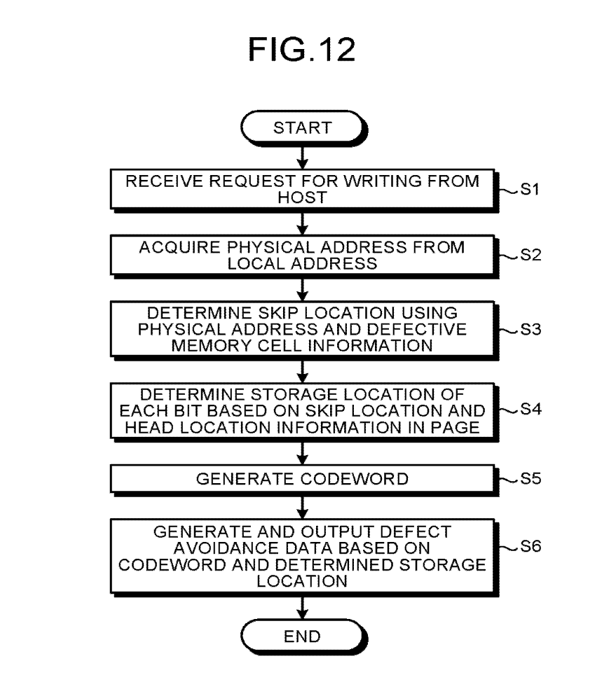

FIG. 12 is a flowchart illustrating an example of the write procedure of this embodiment. As illustrated in FIG. 12, when the write request is received from the host 4 (Step S1), the control unit 23 acquires the physical address from the logical address of the user data requested for the writing (Step S2). Next, the storage location control unit 26 determines a location to be skipped (a skip location) using the physical address and the defective memory cell information (Step S3). Then, the storage location control unit 26 determines the storage location of each codeword based on the skip location and head location information in the page (Step S4). In other words, for example, the storage location illustrated in the second stage of FIG. 9 or 11 is determined. Further, the head location information in the page is information indicating a location (the column address) of the head of each area illustrated in FIG. 8. In addition, the encoder 241 encodes the division data obtained by dividing the user data of one page into plural data to generate the codeword (Step S5). Further, Step S5 is not necessarily performed after Step S4. In general, when the control unit 23 receives the write request, the encoder 241 is instructed to perform the encoding so as to start the encoding.

The storage location control unit 26 generates and outputs the defect avoidance data based on the codeword output from the encoder 241 and the storage location of each bit determined in Step S4 (Step S6). The above processes are performed by the page unit. Further, in a case where the randomization is performed, the storage location control unit 26 performs the process of Step S6 on the codeword after being subjected to the randomization.

Further, FIG. 12 illustrates an example of performing the skip process, but in a case where the replacement process is performed, the storage location control unit 26 determines a location for the replacement using the physical address and the defective memory cell information in Step S3 of FIG. 12. Specifically, the bit location corresponding to the defective memory cell is acquired as the first bit location, and a location (a second location) where a bit value to be written to the first bit location is written is determined. The second location is a location in the redundant area (β bits) of each area as illustrated in FIG. 8 described above. The storage location control unit 26 stores a correspondence between the first bit location and the second bit location.

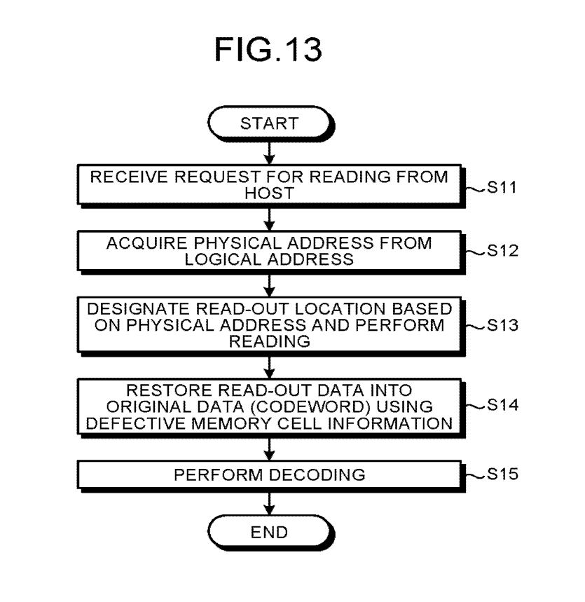

FIG. 13 is a flowchart illustrating an example of a read procedure of this embodiment. Herein, as described above, since the reading can be performed in the codeword unit, the process of FIG. 13 is performed on each codeword to be read. As illustrated in FIG. 13, when the read request is received from the host 4 (Step S11), the control unit 23 acquires the physical address from the logical address of the user data requested for the reading (Step S12). Next, the control unit 23 designates a read-out location (the physical address) to the memory I/F 22 and instructs that the reading is performed (Step S13). The memory I/F 22 performs the reading from the semiconductor memory unit 3 based on the instruction from the control unit 23. Next, the storage location control unit 26 restores the data read out of the semiconductor memory unit 3 (Step S14). Specifically, the storage location control unit 26 checks the bit location which is skipped as the defective memory cell in the read-out data using the defective memory cell information, and erases the skipped bit location (that is, the bit where an arbitrary value is inserted at the time of the writing). In addition, in a case where the replacement process is performed at the time of the writing instead of the skip process, the storage location control unit 26 replaces (overwrites) the data at the first bit location (seventh data) with the data (the sixth data) at the second bit location based on the stored correspondence between the first bit location and the second bit location. The decoder 242 decodes the restored data, and performs the error correction in a case where there is an error (Step 15).

Further, the reading may be performed in the page unit instead of the codeword unit. In a case where the reading is performed in the page unit, the reading from the semiconductor memory unit 3 is performed in the page unit and then the storage location control unit 26 restores the original data corresponding to each codeword using the defective memory cell information, and the decoder 242 decodes each data.

In addition, the description above has been made about the example where the data is readable in the codeword unit, but the read-out unit (the read-out unit from the semiconductor memory unit 3) may not be matched with the codeword unit, and even in a case where the data is not encoded, the writing and the reading of this embodiment can be appropriately applied. In other words, when the data in the writing unit (corresponding to the page) to the semiconductor memory unit 3 is set to the page data of a page data length, the read-out unit from the semiconductor memory unit 3 is a second data length (α+β of FIG. 8) including first data of a first data length (corresponding to α of FIG. 8) shorter than the page data length. In a case where a plurality of second data are included in the page data, the writing and the reading of this embodiment can be applied regardless of the necessity of the encoding and the encoding unit. As illustrated in FIG. 8, the second data has a length longer than the first data length. In this case, as described above, the defective cell avoidance process may be performed to write the data of the first data length in each area while avoiding the defective memory cell based on the defective memory cell information. In addition, the original data may be restored using the defective memory cell information at the time of the reading. For example, α bits of FIG. 8 may be the user data including no parity, or α bits of FIG. 9 may be configured by a plurality of codewords. In addition, α bits of FIG. 8 may be data obtained by dividing one codeword into a plurality of data. However, in a case where α bits of FIG. 8 are the data obtained by dividing one codeword into the plurality of data, the decoding is not possible to be performed only in one reading unit at the time of the reading, so that the decoding is performed after the data is read in a plurality of read-out units.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory;
a memory interface configured to control reading/writing data from/to the nonvolatile memory;
a defective memory cell information storage unit configured to store defective memory cell information of the nonvolatile memory; and
a storage location control unit configured to,
in response to a write instruction of a plurality of first data to the nonvolatile memory, each of the plurality of first data having a first data length, create second data for each of the first data based on a memory area in which the first data is to be stored and the defective memory cell information, the second data having a second data length longer than the first data length, and cause the memory interface to write a plurality of second data to the nonvolatile memory, and
in response to a read instruction of the first data, cause the memory interface to read the second data corresponding to the first data from the nonvolatile memory, and restore the first data based on the read second data and the defective memory cell information.

2. The memory system according to claim 1, further comprising:
an encoder configured to encode the data to generate a codeword,
wherein the first data is the codeword.

3. The memory system according to claim 2,
wherein in a case where there is a defective memory cell in the memory area in which the first data is to be stored, the storage location control unit create the second data by inserting fourth data before third data in the first data, a memory cell for storing the third data being the defective memory cell, the fourth data having the same size as that of the third data.

4. The memory system according to claim 3,
wherein the storage location control unit deletes the fourth data in the read second data, and restores the first data.

5. The memory system according to claim 4,
wherein in a case where a data length of the first data with the fourth data inserted is shorter than the second data length, the storage location control unit adds arbitrary data after the first data to create the second data.

6. The memory system according to claim 2,
wherein in a case where there is a defective memory cell in the memory area in which the first data is to be stored, the storage location control unit overwrites sixth data in the first data with arbitrary data and inserts seventh data after the first data to create the second data, a memory cell for storing the sixth data being the defective memory cell, the seventh data being the sixth data before the overwriting.

7. The memory system according to claim 6,
wherein the storage location control unit overwrites eighth data with the seventh data to restore the first data, the eighth data corresponding to the defective memory cell in the read second data.

8. The memory system according to claim 7,
wherein in a case where a data length of the first data into which the seventh data is inserted is shorter than the second data length, the storage location control unit adds arbitrary data after the seventh data to create the second data.

9. The memory system according to claim 1, further comprising:
a randomizer/derandomizer configured to randomize the first data and derandomize the second data of the second data length which is read out of the nonvolatile memory,
wherein the memory interface writes the second data including the randomized first data to the nonvolatile memory.

10. The memory system according to claim 1, further comprising:
a control unit configured to manage a logical address, and a physical address including a page address and a column address corresponding to the logical address, and does not change the column address based on the defective memory cell information, the logical address corresponding to the first data which is user data received from a host, the logical address being capable of being designated by the host.

11. The memory system according to claim 1,
wherein the nonvolatile memory has a memory cell array having a three-dimensional structure.

12. A memory controller comprising:
a memory interface configured to control reading/writing data from/to a nonvolatile memory;
a defective memory cell information storage unit configured to store defective memory cell information of the nonvolatile memory; and
a storage location control unit configured to,
in response to a write instruction of a plurality of first data to the nonvolatile memory, each of the plurality of first data having a first data length, create second data for each of the first data based on a memory area in which the first data is to be stored and the defective memory cell information, the second data having a second data length longer than the first data length, and cause the memory interface to write a plurality of second data to the nonvolatile memory, and
in response to a read instruction of the first data, cause the memory interface to read the second data corresponding to the first data from the nonvolatile memory, and restore the first data based on the read second data and the defective memory cell information.

13. A method of controlling a nonvolatile memory,
the method comprising:
storing defective memory cell information of the nonvolatile memory;
in response to a write instruction of a plurality of first data to the nonvolatile memory, each of the plurality of first data having a first data length, creating second data for each of the first data based on a memory area in which the first data is to be stored and the defective memory cell information, the second data having a second data length longer than the first data length, and writing the plurality of second data to the nonvolatile memory; and
in response to a read instruction of the first data, reading the second data corresponding to the first data from the nonvolatile memory, and restoring the first data based on the read second data and the defective memory cell information.

14. The method according to claim 13, further comprising:
encoding the data to generate a codeword,
wherein the first data is the codeword.

15. The method according to claim 14,
wherein in a case where there is a defective memory cell in the memory area in which the first data is to be stored, the method creating the second data by inserting fourth data before third data, a memory cell for storing the third data being the defective memory cell, the fourth data having the same size as that of the third data.

16. The method according to claim 15, further comprising:
deleting the fourth data in the read first data to restore the first data.

17. The method according to claim 16, further comprising:
in a case where a data length of the first data with the fourth data inserted is shorter than the first data length, adding arbitrary data after the first data to create the second data.

18. The method according to claim 14, further comprising:
in a case where there is a defective memory cell in the memory area in which the first data is to be stored, overwriting sixth data in the first data with arbitrary data and inserting seventh data after the first data to create the second data, a memory cell for storing the sixth data being the defective memory cell, the seventh data being the sixth data before the overwriting.

19. The method according to claim 18, further comprising:
overwriting eighth data with the seventh data to restore the first data, the eighth data corresponding to the defective memory cell in the read first data.

20. The method according to claim 19, further comprising:
in a case where a data length of the first data into which the seventh data is inserted is shorter than the first data length, adding arbitrary data after the seventh data to create the second data.
